(19) United States
(12) Patent Application Publication
(10) Pub. No.: US 2006/0022351 A1
(43) Pub. Date: Feb. 2, 2006

(54) Semiconductor device and method for manufacturing the same, package for LCD driver

(76) Inventor: Hiroki Aisawa, Yamagata (JP)

Correspondence Address: HARNESS, DICKEY & PIERCE, P.L.C., P.O. BOX 828, BLOOMFIELD HILLS, MI, 48303, US

(21) Appl. No.: 11/143,186

(22) Filed: Jun. 2, 2005

(30) Foreign Application Priority Data
Jul. 29, 2004 (JP) 2004-221410

(51) Int. Cl. H01L 23/495

(52) U.S. Cl. 257/783

(57) ABSTRACT

A bump electrode is connected with a semiconductor integrated circuit of a semiconductor chip and is arranged closer to the center than to the chip edge part on a primary surface of the semiconductor chip. Consequently, when connecting the bump electrode with a lead shown in broken line, the lead has a space for itself to favorably deform by the time it reaches above a chip edge part. That is to say that the lead can be positioned far above the chip edge part. As a result, the semiconductor chip can be connected with the lead in a manner that the lead does not easily come in contact with the chip edge part even when the height of the bump electrode is lowered.

### RELATED APPLICATIONS

This Application claims priority to Japanese Patent Application No. 2004-221410 filed Jul. 14, 2004 which is hereby expressly incorporated by reference herein in its entirety.

### BACKGROUND

1. Technical Field

The present invention relates to a semiconductor device and a method for manufacturing the same which accompanies with formation of bump electrodes as outer terminals and a tape carrier package (TCP), particularly to a package for a liquid-crystal device (LCD) driver having a plurality of narrow-pitched bump electrodes.

2. Related Art

A product accompanied with the TCP is assembled by use of a tape automated bonding (TAB) technique. That is to say, bump electrodes as outer terminals are formed on a primary surface of a semiconductor chip, which is then subject to inner lead bonding to be bonded to a film carrier. The film carrier is in a form of longitudinal tape on which wiring patterns are repeatedly formed. The film carrier includes a device hole, at which inner leads are exposed, and outer leads. The film carrier is conveyed automatically from one device hole to another. The semiconductor chip is adjusted into a predetermined position of the device hole, and the bump electrodes and the inner leads are bonded using a technique such as thermo compression. Thereafter, the outer leads of the semiconductor chip are bonded to an essential part of a circuit substrate to produce a TCP product.

The semiconductor chip is produced through a wafer-dicing process. It is better that the width of a scribe region needed for the dicing process is narrower. This is because, the narrower the width of the scribe region, which disappears with use of a dicing blade, the more available region there will be on the chip. In the scribe region, test elements, pads, circuit wires and the like are provided. In other words, there are metal wires in the scribe region. Dicing can be done by using a thinner dicing blade. However, such dicing entails a high risk that metal wire debris remains on the cut surface of the semiconductor chip.

The inner leads of the film carrier have a risk of coming in contact with an edge part of the semiconductor chip. If the metal wire debris remains on the cut surface of the semiconductor chip, as described, short circuit can easily take place. Preventive measures against short circuit are as follows:
(i) Secure the scribe region on the semiconductor chip widely so that there is enough room for the test elements, pads, circuit wires and the like to be provided.

(ii) Thicken the dicing blade, or devise on a dicing method such as dicing twice instead of once. This may prevent the metal wire debris from remaining on the cut surface of the semiconductor chip.

(iii) Raise the position of the bump electrodes of the semiconductor chip as much as possible. This can create more space between the inner lead of the film carrier and the semiconductor chip. Consequently, the inner lead does not easily contact the edge part of the semiconductor chip.

However, with the measures (i) and (ii), it is impossible to broaden the available region of the chip. Also, it takes time to devise the dicing method and costs more for the additional processes. With the measure (iii), it costs more to manufacture the bump electrodes. Particularly, the cost for manufacturing the LCD driver chips and the like having a plurality of narrow-pitched bump electrodes is considerable, and this should be avoided.

Further, there are other measures. For example, the inner lead bonding of the semiconductor chip with the film carrier is conducted by deforming the film carrier in a manner that the edge part of the semiconductor chip and the inner lead become farther away from each other (e.g., Japanese Unexamined Patent Publication No. 2002-9108 (p. 5-6, FIG. 2 and FIG. 3)). In other words, it is a configuration as to avoid short circuit even when the metal wire debris remains on the chip edge part.

In the process of manufacturing the semiconductor device, it is desirable to conduct a simplified dicing, by which the metal wire debris may remain, in order to improve productivity and to broaden the available region of the chips on the wafer. However, this may invite short circuit when the inner lead of the film carrier comes in contact with the chip edge part. A countermeasure against this is to increase the height of the bump electrode. If the bump electrode is near the chip edge part and taller, the inner lead will become far away from the chip edge part. “Patent Document 1,” in which the film carrier is deformed for bonding, depicts the same measure. Then, there is the issue of cost of the bump electrodes. The cost for the LCD driver chip and the like, in particular, having a plurality of narrow-pitched bump electrodes is considerable.

In view of the issues as described above, the invention aims to provide a semiconductor device and a method for manufacturing the same and an LCD driver package, which allow the simplified dicing that may create metal wire debris and which can prevent short circuit of the inner lead of the film carrier while maintaining the height of the bump electrode low.

### SUMMARY

A semiconductor device of the invention includes: a semiconductor chip having a semiconductor integrated circuit composed of a plurality of semiconductor elements; and a plurality of bump electrodes for outer connection being connected with the semiconductor integrated circuit, each arranged closer to a center than to a chip edge part on a primary surface of the semiconductor chip.

According to the semiconductor device of the invention, the bump electrode is provided far from the semiconductor chip edge part. Consequently, when connecting the bump electrode with the lead, the lead has a space for itself to favorably deform by the time it reaches above a chip edge part. That is to say that the lead can be placed at a position far above the chip edge part. As a result, the semiconductor chip can be connected with the lead that does not easily come in contact with the chip edge part even when the height of the bump electrode is lowered.

With the semiconductor device of the invention, the bump electrode uses a wiring pattern as a base using a specified layer of wiring layers composing the semiconductor integrated circuit and is provided on the semiconductor integrated circuit. It is desirable that drawing of the wiring pattern be conducted at an upper layer so as not to overburden designing.

The semiconductor device of the invention includes: a semiconductor chip having a semiconductor integrated circuit composed of a plurality of semiconductor elements; a plurality of bump electrodes for outer connection being connected with the semiconductor integrated circuit, each arranged closer to a center than to a chip edge part on a primary surface of the semiconductor chip; and a film carrier including a plurality of leads supported by an insulating film held above and nearby an edge part of the semiconductor chip, each lead being coupled to each bump electrode as an inner lead.

According to the semiconductor device of the invention, the bump electrode is provided far from the semiconductor chip edge part. Consequently, the inner lead of the film carrier can be easily deformed so as to have an arrangement in which it does not easily contact with the chip edge part by the time it reaches above the chip edge part. Moreover, due to the position of the bump electrodes, the insulating film is held above and nearby the edge part of the semiconductor chip. As a result, the film carrier can have a configuration of the inner leads, in which the inner leads do not easily come in contact with the chip edge part even when the height of the bump electrodes is lowered.

With the semiconductor device of the invention, a more reliable configuration in bonding the film carrier with the semiconductor chip can be obtained by including any of the following characteristics.

That is, the inner lead of the film carrier bends upwards from its connection part with the bump electrode on the primary surface of the semiconductor chip while keeping a certain clearance from the semiconductor chip.

Further, the inner lead of the film carrier bends upwards from its connection part with the bump electrode on the primary surface of the semiconductor chip while keeping a certain clearance from the semiconductor chip and is protected by a resin material covering from the semiconductor chip edge part to part of the nearby insulating film.

According to the semiconductor device of the invention, the semiconductor chip is a chip for a liquid-crystal device (LCD) driver. The LCD driver chip, in particular, has a large number of bump electrodes, which are easily gathered towards the center of the chip along the longitudinal side of the chip, and, therefore, an enormous effect can be exerted.

The method for manufacturing the semiconductor device of the invention includes: as regards a wafer process in which a plurality of semiconductor elements are arranged in each chip region on a semiconductor substrate and in which a semiconductor integrated circuit is fabricated by a specified interconnection of wiring patterns of a plurality of wiring layers via interlayer insulating films, arranging each electrode pad closer to the center of the chip region than to the chip edge part on any of the wiring patterns of the wiring layers; and forming a bump electrode for outer connection on each electrode pad.

According to the method for manufacturing the semiconductor device of the invention, the method is accompanied with drawing of the wiring pattern so as not to overburden designing, and the bump electrode is provided far from the semiconductor chip edge part closer to the chip center. The bump electrode is formed to be relatively low in height. It is because, when connecting the lead, the lead can be easily deformed towards a position where it does not easily contact the chip edge part by the time it reaches above the chip edge part.

The method for manufacturing the semiconductor device of the invention further includes: dicing the semiconductor substrate into semiconductor chips in accordance with each chip region; inner lead bonding in which a film carrier having leads supported by an insulating film is prepared and in which the leads are gang-bonded as inner leads to the respective bump electrodes; and for the film carrier to hold the insulating film above and nearby the edge part of the semiconductor chip following the inner lead bonding.

According to the characteristic as described, it is easy to hold the insulating film above and nearby the semiconductor chip edge part due to the position of the bump electrodes. The film carrier can have a configuration of the inner leads, in which the inner leads do not easily come in contact with the chip edge part even when the height of the bump electrodes is lowered.

In addition, the method for manufacturing the semiconductor device of the invention further includes: dicing the semiconductor substrate into semiconductor chips in accordance with each chip region; inner lead bonding in which a film carrier having leads supported by an insulating film is prepared and in which the leads are gang-bonded as inner leads to the respective bump electrodes; and protecting the inner lead by a resin covering from the semiconductor chip edge part to the part of the nearby insulating film and holding the insulating film with the film carrier above and nearby the edge part of the semiconductor chip after the inner lead bonding.

According to the above-described characteristics, it is easy to hold the insulating film above and nearby the semiconductor chip edge part due to the position of the bump electrode. The film carrier can be configured in a manner that at least the inner lead and the chip edge part do not come in contact with each other, and, further, the configuration is secured by the resin. As a result, a more reliable configuration in bonding the film carrier with the semiconductor chip can be obtained.

The LCD driver package of the invention includes: a semiconductor chip in a shape of rectangular, whose one side has a semiconductor integrated circuit composed of a plurality of semiconductor elements and is five or more times longer than other sides; a plurality of bump electrodes for outer connection being connected with the semiconductor integrated circuit, each arranged along one opposing side of longitudinal sides of and on the primary surface of the semiconductor chip closer to the center than to the chip edge part; a film carrier which has a plurality of leads supported by an insulating film, which includes the insulating film held above and nearby an edge part of the semiconductor chip, and which is configured in a manner that each lead is coupled as an inner lead to the respective bump electrode and that the inner lead bends upwards from its connection part with the bump electrode on the primary surface of the semiconductor chip while keeping a certain clearance from the semiconductor chip; and a protective resin that covers from the semiconductor chip edge part to part of the nearby insulating film while securing a configuration of at least the inner lead of the film carrier.

According to the LCD driver package of the invention, the bump electrode is provided far from the semiconductor chip edge part. Consequently, the inner lead of the film carrier can be easily deformed so as to have an arrangement in which it does not easily contact the chip edge part by the time it reaches above the chip edge part. Moreover, due to the arrangement of the bump electrodes, the insulating film is held above and nearby the edge part of the semiconductor chip. The semiconductor chip and the film carrier are secured by the resin, having a positional relation in which the semiconductor chip and the film carrier do not come in contact with each other near the semiconductor chip edge part. Accordingly, high reliability of the LCD driver package can be maintained even when the height of the bump electrode of the semiconductor chip is lowered.

Further, according to the LCD driver package of the invention, the bump electrode is provided having a specified height in a range of 5-15 μm.

### BRIEF DESCRIPTION OF THE DRAWINGS

FIG. 1 is a cross-sectional view of an essential part of a semiconductor device of a first embodiment.

FIG. 2 is an explanatory diagram exemplifying an essential part of a method for manufacturing the semiconductor device having the structure as one shown in FIG. 1.

FIG. 3 is a plan view of an essential part of a semiconductor device of a second embodiment.

FIG. 4 is a cross-sectional view of the structure of FIG. 3.

FIG. 5 is a diagram showing a resin encapsulation configuration of FIG. 4 at an essential part of the semiconductor device of a third embodiment.

FIG. 6 is a plan view of an essential part of a semiconductor device of a fourth embodiment.

FIG. 7 is a cross-sectional view of the structure of FIG. 6.

### DETAILED DESCRIPTION

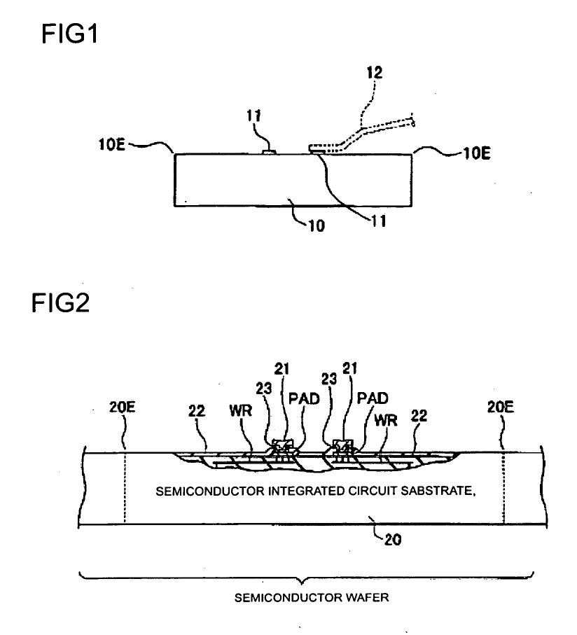

FIG. 1 is a cross-sectional diagram showing an essential part of the semiconductor device of the first embodiment of the invention. Inside a semiconductor chip 10, which is not shown, is a semiconductor integrated circuit composed of a plurality of semiconductor elements. The semiconductor chip 10 includes a bump electrode 11 as the outer terminal. The bump electrode 11 is connected with the semiconductor integrated circuit of the semiconductor chip 10 and is formed on a pad (not shown) which was formed on specified wiring patterns. Here, the bump electrodes 11 are each arranged closer to the center than to the chip edge part on the primary surface of the semiconductor chip 10.

According to the embodiment, the bump electrode 11 is provided at a position as far as possible from an edge part 10E of the semiconductor chip 10. Consequently, when connecting the lead 12 shown in broken line with the bump electrode 11, there is a room for the lead 12 to be favorably deformed by the time it reaches above the chip edge part 10E. That is, the lead 12 can be positioned far above the chip edge part 10E. Accordingly, the semiconductor chip 10 can be connected with the lead 12 that does not readily come in contact with the chip edge part 10E even when the height of the bump electrode 11 is lowered. The lead 12 can be arranged so as to have enough distance from the chip edge part 10E and to avoid any debris of metal wire that may be left on the chip edge part 10E. Further, the lead 12 is often coated with an insulating film except for the end connection area of the lead 12. Due to the position of the bump electrode 11, it is easy to dispose the part of the insulating film over the chip edge part 10E. Resin encapsulation (not shown) may be conducted while keeping the position of the lead 12 and, therefore, contributes to preventing short circuit while keeping the height of the bump electrode low.

FIG. 2 is an explanatory diagram exemplifying an essential part of the method for manufacturing the semiconductor device, as one shown in FIG. 1, of the invention. The semiconductor integrated circuit is in a form of a semiconductor wafer before being diced into semiconductor chips 20 and has a plurality of semiconductor elements (not shown) formed thereon. Also, the semiconductor integrated circuit is fabricated by a specified interconnection of wiring patterns of a plurality of wiring layers via the interlayer insulating films in a manner that these semiconductor elements are interrelated. Each electrode pad PAD is arranged closer to the center of the chip 20 than to a chip edge part 20E by any wiring pattern WR of the wiring layers. It is desirable that the drawing be carried out with the wiring pattern at the upper possible layers so as not to overburden designing. A passivation layer 22 is formed around each electrode pad PAD. A bump electrode 21 is formed on top of each electrode pad PAD.

Thus, the bump electrode 21 has a composition of a bump on the active surface of the chip, provided closer to the center at the upper part of the semiconductor integrated circuit. However, by revising the design, it is possible not to provide any elements below the bump electrode 21. Consequently, it becomes possible to arrange the bump electrode 21 as a bump on the non-active surface closer to the center of the semiconductor chip 20.

The bump electrode 21 is a gold bump, for example, and is formed as follows. First, a barrier metal 23 such as a TiW/Au laminated layer is formed on the passivation film 22 including the electrode pad PAD and up. Next, a resist (not shown) is coated to form a resist pattern. The resist pattern forms a predetermined aperture above the electrode pad PAD. Gold plating is done by electroplating in accordance with the resist pattern. Thereafter, the resist pattern is removed, and, by using the formed gold plate on the electrode pad PAD as a mask, unnecessary barrier metal on the passivation film 22 is removed by etching. As a result, the bump electrode 21 is formed. As previously mentioned, the height of the bump electrode 21 may be lowered so as to help reduce the cost of the bumps.

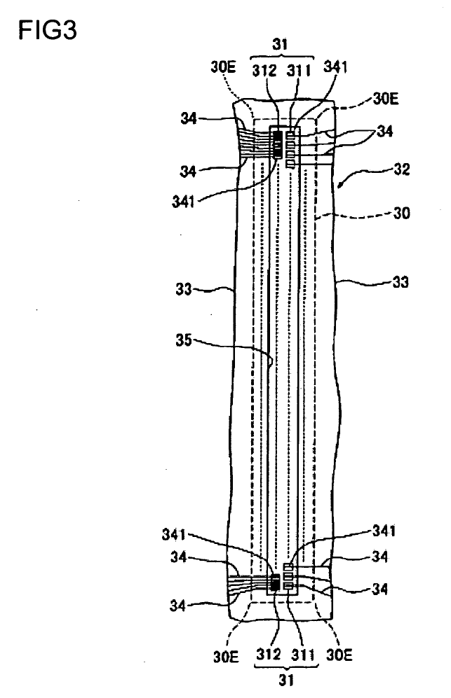

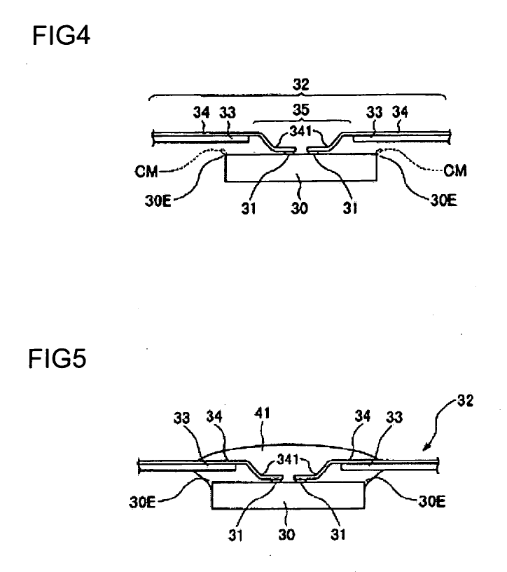

FIG. 3 is a plan view showing the essential part of the semiconductor device of the second embodiment of the invention. Further, FIG. 4 is a cross-sectional view of the structure of FIG. 3.

A semiconductor chip 30 is a LCD driver chip, for example. The LCD driver chip is rectangular in shape, whose one side has a semiconductor integrated circuit composed of a plurality of semiconductor elements and is five or more times longer than other sides.

Although not shown in the drawings, the semiconductor integrated circuit inside the LCD driver chip is composed of an input circuit section into which signal data is input, a storage section composed of random access memory (RAM) and the like, a logic circuit section made of gate arrays and the like as a data processing section, and an output circuit section containing latch circuits for outputting signals, each section correlating with one another.

As the LCD driver chip, the semiconductor chip 30 contains a large number of narrow-pitched bump electrodes 31 (311, 312) corresponding to the input and output circuit sections. Particularly, alignment of the bump electrodes 312 on the side of the output circuit section is narrower-pitched, and there are a very large number of the bump electrodes. These bump electrodes 31 are each arranged closer to the center than to a chip edge part 30E on the primary surface of the semiconductor chip 30. As shown in FIG. 2, these bump electrodes 31 are formed on the pads which are put closer to the chip center by specified wiring patterns.

A film carrier 32 includes a plurality of leads 34 supported by an insulating film 33. The film carrier 32 has a device hole 35 at which the leads 34 are exposed as inner leads 341. Each inner lead 341 is connected to each bump electrode 31 of the semiconductor chip 30. To connect the inner lead 341 with the bump electrode 31, the well-known TAB technique is used. That is, the film carrier 32 is automatically conveyed from one device hole 35 to another. The semiconductor chips 30 are adjusted into specified positions of the device hole, and the bump electrodes 31 and the inner leads 341 are gang-bonded by a technique such as thermo compression using a bonding tool.

The inner lead 341 is configured as to be bent upwards from its connection part with the bump electrode 31 on the primary surface of the semiconductor chip 30 and to have a certain clearance from the semiconductor chip 30 at the chip edge part 30E. This configuration is made possible by arranging the bump electrodes 31 closer to the center of the semiconductor chip 30. This means that, by the time the lead 34 reaches above the chip edge part 30E, the lead 34 can be easily deformed towards the position where it does not easily come in contact with the chip edge part 30E.

Further, the film carrier 32 is configured in a manner that the insulating film 33 is held above and nearby the chip edge part 30E. This configuration also is naturally possible because the bump electrodes 31 are arranged closer to the center of the semiconductor chip 30. That is, because the gap between the bump electrode 31 and the chip edge part 30E is larger, the film carrier 32 is configured so as to cover a region of the insulating film 33 that supports the lead 34 above the chip edge part 30E.

The insulating film 33 is a polyimide film, for example, having a thickness of 100 μm or less, namely about 70-80 μm, for example. On the insulating film 33, the lead 34 having a thickness of 30 μm or less, namely about 10-20 μm, for example, is formed.

In FIG. 4, a broken line CM indicates, for example, debris that may remain on the chip edge part 30E after dicing the wafer into the semiconductor chips 30. As was described, even when the debris CM of the metal wire remains on the chip edge part 30E, the lead 34 can be arranged to have enough distance from the debris CM to avoid the same. Further, the lead 34 is protected by the insulating film 33 above the chip edge part 30E. Even when the lead 34 approaches the chip edge part 30E, the insulating film 33 will contact the chip edge part 30E, and the lead 34 is protected causing no short circuits.

According to the configuration of the above-referenced embodiment, the bump electrode 31 contributes to preventing short circuits while staying low in height. If a conventionally required height of the bump electrode of the LCD driver chip, on which bump electrodes are arranged closer to the chip edge part, is around 20 μm, the height of the bump electrode 31 employing the configuration of the invention can be about 10 μm, which is about 50% shorter. The bump electrode 31 can fully maintain its reliability insofar as a given height of the bump electrode 31 is in the range of 5-15 μm. Consequently, a simplified dicing that may leave the metal wire debris becomes possible, and the TCP product that does not reduce its reliability can be realized while reducing the cost of the bumps.

FIG. 5 is a diagram showing an essential part of the semiconductor device of the third embodiment of the invention and showing the resin encapsulation using the composition of FIG. 4. The same numerals are given to elements that are identical to those in the second embodiment. That is to say, the inner lead 341 of the film carrier 32 bends upward, as described, on the primary surface of the semiconductor chip 30 at its connection part with the bump electrode 31, while keeping a certain clearance from the semiconductor chip 30. In order to secure this configuration, a resin material 41 covers the inner leads 341, stretching from the edge part of the semiconductor chip 30 to the part of the nearby insulating film 33.

An example method for encapsulating the resin material 41 is as follows. After the process of inner lead bonding of the semiconductor chip 30 with the film carrier 32, a fluid resin such as epoxy resin or the like is coated and fixed. The resin material 41 covers and hardens the inner lead 341 covering from the edge part of the semiconductor chip 30 to the part of the nearby insulating film 33. The resin material 41 can be of any material and is not limited to epoxy resin insofar as it protects and secures the configuration of the inner leads 341 or the leads 34 on and surrounding the semiconductor chip 30.

According to the configuration of this embodiment, the same effect as that of the second embodiment can be exerted. Due to the position of the bump electrode 31, the height of the bump electrode 31 can be lowered, and it becomes possible to hold the insulating film of the film carrier 32 above and nearby the semiconductor chip. The film carrier 32 can have the configuration in which at least the inner lead 341 and the chip edge part 30E do not come in contact with each other, and, further, this configuration can be secured by the resin material 41. Consequently, a more reliable configuration in bonding the film carrier with the semiconductor chip can be obtained.

In the second and third embodiments, the LCD driver chip was exemplified as the semiconductor device. The LCD driver chip, in particular, has a large number of bump electrodes, and, because it is easy to gather the bump electrodes towards the center of the chip on the longitudinal side of the chip, an enormous effect is to be exerted if the configuration of the invention is employed. However, the configuration of the invention can be used not only for the LCD driver chip but also for other TCP products.

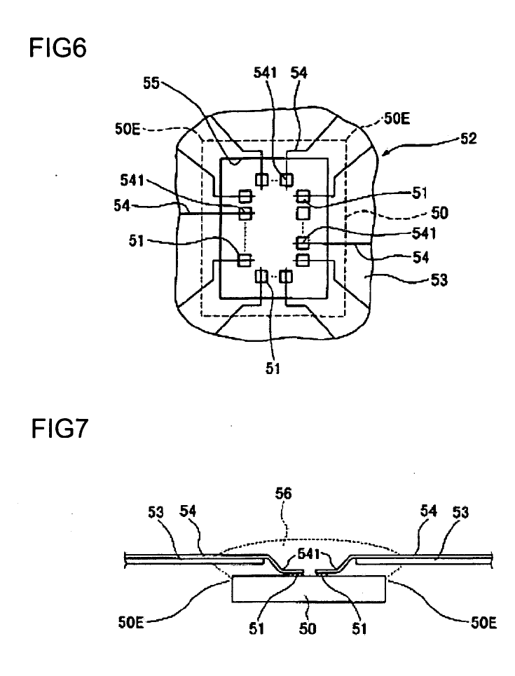

FIG. 6 is a plan view of an essential part of the semiconductor device of the fourth embodiment of the invention. FIG. 7 is a cross-sectional view of the structure of FIG. 6.

A semiconductor chip 50 includes bump electrodes 51. As shown in the previous embodiments of the invention, the bump electrodes 51 are each arranged on the primary surface of the semiconductor chip 50 as close as possible to the center than to the chip edge part 50E. As shown in FIG. 2, the bump electrodes 51 are formed on the pads that are gathered closer to the chip center by specified wiring patterns.

A film carrier 52 includes a plurality of leads 54 supported by an insulating film 53. The film carrier 52 also includes device holes 55 at which the leads 54 are exposed as inner leads 541. Each inner lead 541 is connected to each bump electrode 51 of the semiconductor chip 50. To connect the inner lead 541 with the bump electrode 51, the well-known TAB technique is used.

The inner lead 541 is configured so as to bend upwards from its connection part with the bump electrode 51 on the primary surface of the semiconductor chip 50 and, at the chip edge part 50E, to keep a certain clearance from the semiconductor chip 50. Further, the film carrier 52 is configured so as to hold the insulating film 53 above and nearby the chip edge part 50E. Both configurations are made possible by arranging the bump electrodes 51 closer to the center of the semiconductor chip 50 as described in the second embodiment. Even when the lead 54 approaches the chip edge part 50E, it is protected by the insulating film 53. Further, due to the position of the bump electrodes 51, the film carrier 52 can have the configuration in which the inner leads do not easily come in contact with the chip end part 50E even when the height of the bump electrodes 31 is lowered.

In addition, after the process of inner lead bonding of the semiconductor chip 50 with the film carrier 52, a resin material 56 shown in broken line covers and hardens the inner leads 541 including the edge part of the semiconductor chip 50 to the part of the nearby insulating film 53. Consequently, the configuration of the inner leads 541 or the leads 54 on and surrounding the semiconductor chip 50 are protected and secured.

With the configuration of the embodiment above, also, the same effect as that in the second embodiment can be exerted. That is, due to the position of the bump electrodes 51, the height of the bump electrodes can be lowered, and, further, it becomes easy to hold the insulating film 53 of the film carrier 52 above and nearby the semiconductor chip 50. The film carrier 52 can be configured in a manner that at least the inner leads 541 do not easily come in contact with the chip edge part 50E, and, further, such configuration is secured by the resin material 56. As a consequence, a more reliable configuration in bonding the film carrier 52 with the semiconductor chip 50 can be obtained.

According to each of the embodiments, the bump electrode is placed far from the edge part of the semiconductor chip. By doing so, when connecting the lead with the bump electrode, the lead can be easily deformed so as not to easily come in contact with the chip edge part by the time it reaches above the chip edge part. Moreover, due to the arrangement of the bump electrodes, the insulating film is held above and nearby the semiconductor chip. As a consequence, the film carrier can have a configuration of the inner leads that do not easily come in contact with the chip edge part even when the bump electrode is lowered. Further, when such inner lead configuration is fixed by the resin material, a more reliable configuration in bonding the film carrier with the semiconductor chip can be obtained. As a result, the semiconductor device and the method for manufacturing the same and the LCD driver package can be provided at low cost while allowing the simplified dicing that may leave the metal wire debris, preventing short circuiting of the inner leads of the film carrier, and keeping the height of the bump electrode low.

What is claimed is:

1. A semiconductor device, comprising:
a rectangular semiconductor chip; and
bump electrodes on the semiconductor chip;
wherein the bump electrodes are arranged closer to a longitudinal center line of the semiconductor chip than to a longitudinal chip edge of the semiconductor chip.

2. The semiconductor device according to claim 1, further comprising:
at least one lead connected to the bump electrodes;
wherein the lead is curved above the semiconductor chip.

3. The semiconductor device according to claim 2, further comprising:
a film carrier that supports the lead; and
an insulating film formed on at least the semiconductor chip side of the lead;
wherein at least a portion of the insulating film is located above the semiconductor chip.
